(19) United States
(12) Patent Application Publication
(10) Pub. No.: US 2026/0088271 A1
(43) Pub. Date: Mar. 26, 2026

(54) METHOD FOR PRODUCING AN ELECTRODE, ELECTRODE, ALKALINE BATTERY, AND USES OF THE ALKALINE BATTERY

(71) Applicant: FRAUNHOFER-GESELLSCHAFT ZUR FÖRDERUNG DER ANGEWANDTEN FORSCHUNG E.V., München (DE)

(72) Inventors: Kai Peter BIRKE, Stuttgart (DE); Kathrin SCHAD, Stuttgart (DE); Max WEEBER, Stuttgart (DE)

(73) Assignee: FRAUNHOFER-GESELLSCHAFT ZUR FÖRDERUNG DER ANGEWANDTEN FORSCHUNG E.V., München (DE)

(21) Appl. No.: 19/108,881

(22) PCT Filed: Aug. 17, 2023
(86) PCT No.: PCT/EP2023/072722

§ 371 Date: Mar. 5, 2025

(30) Foreign Application Priority Data
Sep. 8, 2022 (DE) 10 2022 209 362.3

(51) Int. Cl. H01M 4/04; H01M 4/02; H01M 4/38; H01M 4/505; H01M 4/525; H01M 4/58; H01M 4/583; H01M 4/66; H01M 10/056; H01M 50/417; H01M 50/423; H01M 50/426; H01M 50/434; H01M 50/491; H10D 10/01

(52) U.S. Cl. CPC H01M 4/0416; H01M 4/382; H01M 4/386; H01M 4/505; H01M 4/525; H01M 4/5825; H01M 4/583; H01M 4/661; H01M 10/056; H01M 50/417; H01M 50/423; H01M 50/426; H01M 50/434; H01M 50/491; H10D 10/052; H01M 2004/021; H01M 2004/028; H01M 2300/002; H01M 2300/0028

(57) ABSTRACT

Disclosed are a method for producing an electrode for a galvanic cell, an electrode for a galvanic cell, a galvanic cell, and uses of the galvanic cell. The method comprises: applying a separator membrane to a planar electrode such that an intermediate space is formed between the planar electrode and the separator membrane; subsequently applying a liquid comprising a particular material to the separator membrane, wherein the liquid comprising material penetrates, by way of capillary forces, at least into the pores of the separator membrane, into the intermediate space between the planar electrode and the separator membrane and into pores of the planar electrode, wherein the liquid is subsequently evaporated. The method makes it easily and inexpensively possible to provide an electrode which exhibits a high energy density at the cell level and high chemical, electrochemical and mechanical stability, exhibits high cycle stability and allows high operating currents.

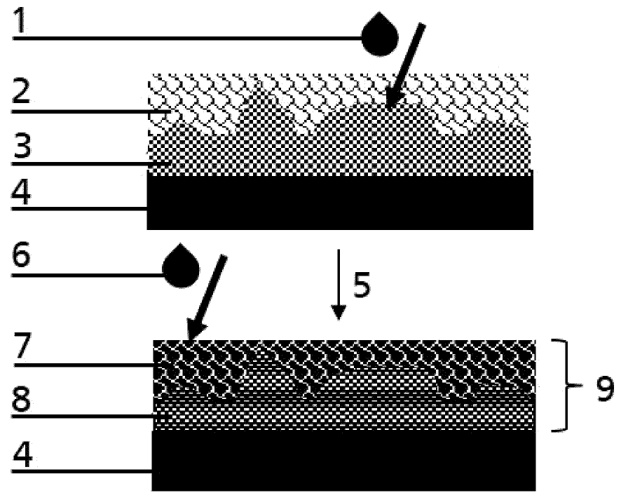

Disclosed are a method for producing an electrode for a galvanic cell, an electrode for a galvanic cell, a galvanic cell, and uses of the galvanic cell. The method comprises applying a separator membrane to a planar electrode such that an intermediate space is formed between the planar electrode and the separator membrane; subsequently applying a liquid comprising a certain material to the separator membrane, wherein the liquid comprising material penetrates, by way of capillary forces, at least into the pores of the separator membrane, into the intermediate space between the planar electrode and the separator membrane and into pores of the planar electrode, wherein the liquid is subsequently evaporated. The method makes it easily and inexpensively possible to provide an electrode which exhibits a high energy density at the cell level and high chemical, electrochemical and mechanical stability, and which thus exhibits high cycle stability and allows high operating currents.

Commercial alkaline batteries (e.g., lithium-ion batteries with a graphite anode) have reached a limit in terms of possible energy density due to the materials used. In addition to the increasing performance requirements, high process-and delivery-related material costs are creating a need for alternative anode approaches.

To improve the energy density of galvanic cells, it has been suggested in the literature to use lithium metal, lithium metal alloys or sodium metal alloys (e.g., an LiAl alloy or an NaAl alloy) instead of a commercial graphite-based negative electrode (anode). However, the use of pure metallic lithium or metal alloys results in insufficient cycle stability and is associated with high production and material costs. For the accessibility and stabilization of these promising high-capacity electrode materials, pretreatment measures at the electrode-electrolyte interface are therefore essential.

CN 112670673 A discloses a separator coated with an active layer, wherein the active layer comprises an organic binder and inorganic particles and a lithium conducting salt. To produce an electrode, the finished separator is applied to a conductive substrate, wherein an electrode is created of which the mechanical stability and possible operating currents or achievable energy density could be further improved. The use of inorganic particles, especially in the case of a lithium foil as a conductive substrate, makes the production of the electrode complex and cost-intensive.

Proceeding from this basis, the object of the present invention was to provide a method for producing an electrode for a galvanic cell, an electrode for a galvanic cell, and a galvanic cell that does not have the disadvantages of the prior art. In particular, the method should be simple and cost-effective in providing an electrode that, when used in a galvanic cell, has a high energy density at the cell level, high chemical, electrochemical and mechanical stability, and thus high cycle stability and high operating currents. Furthermore, uses of the galvanic cell should be proposed.

The object is achieved by the method having the features of claim 1, the electrode having the features of claim 10, the galvanic cell having the features of claim 17, and the use having the features of claim 18. The dependent claims describe advantageous developments.

In accordance with the invention, method is provided for producing an electrode for a galvanic cell, comprising the steps of
a) providing a planar electrode, wherein the planar electrode has a surface;
b) applying a first surface of a separator membrane to the surface of the planar electrode so that an intermediate space is formed between the surface of the planar electrode and the first surface of the separator membrane;
c) applying a liquid to a second surface of the separator membrane opposite the first surface, wherein the liquid comprises a solvent and a material selected from the group consisting of polymer, inorganic particles, organic particles and combinations thereof, wherein the liquid comprising its solvent and its material penetrates, by way of capillary forces, at least into the pores of the separator membrane, into the intermediate space between the surface of the electrode and the first surface of the separator membrane, and into pores of the surface of the planar electrode; and
d) evaporating the solvent of the liquid, wherein an electrode is created, which comprises the material of the liquid in the intermediate space between the surface of the electrode and the first surface of the separator membrane and in at least a portion of the pores, wherein the material contacts the surface of the electrode and the first surface of the separator membrane extensively.

The method according to the invention may be carried out in a simple and cost-effective manner. The method according to the invention furthermore makes it possible to produce an electrode which exhibits a high energy density at the cell level and high chemical, electrochemical and mechanical stability, and which thus exhibits high cycle stability and allows high operating currents. The reason for this is that after evaporation of the liquid, the material of the liquid is present in the pores of the separator membrane, in the intermediate space between the surface of the electrode and the first surface of the separator membrane, and in the pores of the surface of the planar electrode. This penetration of the material of the liquid creates an enriched material layer in the pores of the separator membrane, in the intermediate space and in the pores of the planar electrode. When a liquid electrolyte is added, this enriched material layer ensures an optimal electrolyte distribution at the interface and in the pores of the planar electrode by the formation of a concentration gradient. In addition, the enriched material layer forms a porous supporting structure that promotes the formation of an immobilized, stable protective layer (solid electrolyte interface, SEI) between the electrolyte and the electrode surface. Furthermore, the material of the material layer provides strong adhesion of the separator membrane to the planar electrode. The stated aspects give the electrode a high cycle stability, which means that electrode materials that are critical in terms of stability (such as an LiAl alloy) with a high specific capacity may be used. In this way, high energy densities are realizable at the cell level.

The material may be suitable for swelling into a gel with a liquid electrolyte. This leads to an improved electrolyte distribution and thus ion conduction at the surface of the planar electrode. Since the material is also present in the pores of the separator membrane and in the pores of the surface of the planar electrode, the liquid electrolyte is also present in the pores of the separator membrane and the surface of the planar electrode after the swelling process, surface of the planar electrode, which leads to improved ion transport from the second surface of the separator membrane to the surface of the planar electrode, which increases the energy density compared to known electrodes for galvanic cells. After the material has swelled with the liquid electrolyte, a so-called “solid electrolyte interface” (for short: SEI) is formed in the intermediate space between the separator membrane and the planar electrode and in the pores of the separator membrane and the surface of the electrode and is fixed strongly to the respective surfaces and is immobilized. The resulting stable protective layer increases the chemical and electrochemical stability of the electrode and provides a mechanical barrier that slows down potential dendrite growth. The electrode thus has a higher cycle stability and operational reliability compared to similar electrodes for galvanic cells.

The planar electrode used in the method may comprise or consist of an alkali metal, which is optionally coated on a metal selected from the group consisting of stainless steel, nickel, copper, indium, aluminium and combinations thereof. The alkali metal is preferably selected from the group consisting of lithium, sodium and combinations thereof. The advantage of lithium is its high specific capacity of >3000 Ah/kg (ten times the value of commercial graphite anodes), its low anode potential of 0 V vs. Li/Li⁺ and the resultant very high energy density at the cell level.

The planar electrode used in the method may further comprise or consist of carbon, preferably a carbon selected from the group consisting of graphite, graphene and combinations thereof.

Apart from that, the planar electrode used in the method may comprise or consist of silicon, a silicon alloy and/or a silicon composite.

In addition, the planar electrode used in the method may comprise or consist of a metal selected from the group consisting of stainless steel, nickel, copper, indium, aluminium, preferably aluminium. One advantage of aluminium is that it is cheaper than other suitable alloying elements such as indium or silicon. Further advantages of aluminium are its low anode potential (U_anode), which for an LiAl alloy is around 0.3 V vs Li⁺ (comparable to the potential level of the graphite anode used commercially) and leads to the maximization of the cell voltage U=U_cathode−U_anode. Furthermore, aluminium may provide a high specific capacity (e.g., in the alloy form LiAl approximately 993 Ah/kg, which is about three times that of graphite). In this way, the energy density E providable at the cell level (E=C*U) is very high in the case of an aluminium-based anode. The aluminium is optionally alloyed, preferably with at least one element selected from the second main group of the periodic table, the third main group of the periodic table, the fourth main group of the periodic table, a subgroup of the periodic table and combinations thereof, wherein the at least one element is preferably selected from the group consisting of magnesium, indium, zinc, tin, silicon, manganese and combinations thereof.

The planar electrode used in the method may further comprise or consist of a cathode material preferably selected from the group consisting of nickel manganese cobalt oxide, lithium iron phosphate, lithium manganese oxide, lithium nickel manganese oxide, lithium nickel oxide, lithium cobalt oxide, lithium aluminum nickel oxide, lithium manganese phosphate, lithium iron manganese phosphate, and combinations thereof.

The planar electrode used in the method may have a thickness, in a direction perpendicular to the surface of the planar electrode, in the range from 5 to 100 μm, preferably 10 to 50 μm, particularly preferably 20 to 40 μm.

Furthermore, the surface of the planar electrode used in the method may have a surface structuring. The surface structuring preferably has a structure depth in the range from 1 nm to 100 μm, wherein the surface structuring is particularly preferably selected from the group consisting of embossed surface structuring, brushed surface structuring, patterned surface structuring, corrugated surface structuring and combinations thereof.

The separator membrane used in the method may consist of at least one layer, optionally also at least one further layer (i.e., at least two layers).

The at least one layer (optionally also at least one further layer) may comprise or consist of an electrically insulating material, wherein the material preferably has a specific electrical resistance of ≥10¹⁰ Ω·mm²/m, particularly preferably ≥10¹¹ Ω·mm²/m.

Furthermore, the at least one layer (optionally also at least one further layer) may comprise or consist of an organic material, preferably may comprise or consist of a polymeric plastic. The polymeric plastic is particularly preferably selected from the group consisting of polyolefin, fluoropolymer, polyamide, polyimide and combinations thereof, wherein the polymeric plastic is in particular selected from the group consisting of polyethylene, polypropylene, polytetrafluoroethylene, polyamide, para-aramide, polyimide and combinations thereof.

Furthermore, the at least one layer (optionally also at least one further layer) may comprise or consist of an organic material, preferably may comprise or consist of a ceramic material. The ceramic material is particularly selected from the group consisting of oxide ceramics, carbide ceramics, nitride ceramics and phosphate ceramics. The oxide ceramic may be aluminium oxide (Al₂O₃). Al₂O₃ has the advantage of being cost-effective compared to solid electrolyte salts such as lithium phosphorus sulfide. Furthermore, Al₂O₃ forms an inert protective layer and thus no unwanted side reactions. In addition, Al₂O₃ (in the form of particles) provides a porous structure, which improves electrolyte distribution and has an SEI precursor effect.

Apart from that, the at least one layer (optionally also at least one further layer) may comprise or consist of an ion-conductive material.

Furthermore, the at least one layer (optionally also at least one further layer) may have a thickness, in a direction perpendicular to the surface of the planar electrode, in the range from 1 μm to 300 μm, preferably in the range from 1 μm to 100 μm.

In addition, the at least one layer (optionally also at least one further layer) may have a porosity in the range from 30% to 70%, preferably in the range from 40% to 60%, particularly preferably in the range from 45% to 50%.

The liquid used in the method may comprise a solvent that has a boiling point of ≤156° C., preferably ≤80° C., particularly preferably ≤56° C., at atmospheric pressure. The liquid used in the method may further comprise a solvent that has a vapour pressure at 20° C. of ≥3 hPa, preferably ≥58 hPa, particularly preferably ≥246 hPa. The solvent may be selected from the group consisting of acetone, DEC, DMAC, 3-hexanone, THF, butanone, 3-pentanone, toluene, p-xylene, ethanol and mixtures thereof, wherein the solvent is in particular acetone. The advantage of a solvent with a low boiling point and high vapour pressure is that the method is less energy-intensive, i.e., it may be carried out more economically.

The material of the liquid used in the method may comprise or consist of a polymer dissolved in the solvent.

The polymer may comprise or consist of a non-ion-conducting polymer and/or an ion-conducting polymer. For example, the polymer may comprise or consist of a fluoropolymer and/or a polyethylene oxide, wherein the fluoropolymer is preferably selected from the group consisting of PVDF-HFP, PVDF and combinations thereof. The advantage of PVDF-HFP is that it dissolves very well in acetone and forms a network polymer, i.e., a supporting matrix that improves electrolyte distribution and serves as a fixative for an SEI.

The polymer may be present in the liquid in a concentration from 60 wt. % to 80 wt. %, preferably 65 wt. % to 75 wt., in particular 70 wt. % in relation to the total weight of the liquid.

The material of the liquid used in the method may comprise or consist of inorganic particles which are dispersed in the solvent.

The inorganic particles may be non-electrically conductive inorganic particles, preferably non-electrically conductive ceramic particles.

The particles may further be ion-conducting inorganic particles, particularly preferably ion-conducting inorganic particles comprising or consisting of a sulfidic salt, wherein the sulfidic salt is particularly selected from the group consisting of lithium phosphorus sulfide (Li₃PS₄), lithium germanium phosphorus sulfide (Li₁₀GeP₂S₁₂), lithium silicon phosphorus sulfide, (Li₁₁Si₂PS₁₂), LiGPS₅Cl, Li₆PS₅Br and combinations thereof. The advantage of sulfide salts is that a high ionic conductivity is achieved that is comparable to that of commercial liquid electrolytes.

In the method, the evaporation of the solvent from the liquid may take place at a temperature in the range of 20 to 30° C., preferably at 25° C. This is particularly energy-efficient because evaporation may take place at ambient temperature and no additional heat energy needs to be supplied for evaporation.

After step d), the method may further comprise applying a liquid electrolyte for a galvanic cell to the second surface of the separator membrane, wherein the liquid electrolyte penetrates, by way of capillary forces, at least in a portion of the pores of the separator membrane, into the intermediate space between the surface of the planar electrode and the first surface of the separator membrane and into the pores of the surface of the planar electrode, wherein the liquid electrolyte contacts in particular the surface of the planar electrode and the first surface of the separator membrane.

The liquid electrolyte used for this purpose may comprise a liquid selected from the group consisting of EC, PC, DMC, EMC, DEC, VEC, VC, FEC, TBAC (acetyltributyl citrate), GTB (glycerol tributyrate), GTA (glycerol triacetate), y-buthyrolactone and combinations thereof, wherein the liquid is preferably selected from the group consisting of PC, FEC, EC, VEC, TBAC, GTB, GTA and combinations thereof. The advantage of PC, FEC, EC, VEC, TBAC, GTB, GTA lies in their high boiling point and temperature resistance, which reduces the risk of fire and increases operational safety.

Furthermore, the liquid electrolyte used for this purpose may comprise a lithium conducting salt, wherein the lithium conducting salt is preferably selected from the group consisting of LiPF₆, LiClO₄, LiNO₃, C₆H₁₈LiNSi₂, F₂LiNO₄S₂, C₂F₆LiNO₄S₂, LiB[C₂O₄]₂, LiBF₄ and combinations thereof.

Apart from that, the liquid electrolyte used for this may comprise a sodium conducting salt, wherein the sodium conducting salt is preferably selected from the group consisting of NaPF₆, NaBF₄, NaTF, NaTFSI, NaClO₄ and combinations thereof.

Furthermore, an electrode for a galvanic cell is provided in accordance with the invention, comprising or consisting of
a) a planar electrode, wherein the planar electrode has a surface;
b) a separator membrane having a first surface, a second surface opposite the first surface, and pores, wherein the first surface of the separator membrane is applied to the surface of the planar electrode, and there is an intermediate space between the surface of the planar electrode and the first surface of the separator membrane; and
c) at least one material selected from the group consisting of polymer, inorganic particles, organic particles, and combinations thereof, wherein the material is arranged in at least a portion of the pores of the separator membrane, is arranged in the intermediate space between the surface of the planar electrode and the first surface of the separator membrane, and is arranged in pores of the surface of the planar electrode, and wherein the material contacts the first surface of the separator membrane and the surface of the planar electrode in extensively.

The electrode according to the invention has a high energy density at the cell level as well as high chemical, electrochemical and mechanical stability. Consequently, the electrode according to the invention has a high cycle stability and enables high operating currents.

The planar electrode may comprise or consist of an alkali metal, optionally coated on a metal selected from the group consisting of stainless steel, nickel, copper, indium, aluminium and combinations thereof. The alkali metal is preferably selected from the group consisting of lithium, sodium and combinations thereof. The advantage of lithium is its high specific capacity of >3000 Ah/kg (ten times the value of commercial graphite anodes), its low anode potential of 0 V vs. Li/Li⁺ and its very high energy density.

Furthermore, the planar electrode may comprise or consist of carbon, preferably a carbon selected from the group consisting of graphite, graphene and combinations thereof.

In addition, the planar electrode may comprise or consist of silicon, a silicon alloy and/or a silicon composite.

Apart from that, the planar electrode may comprise or consist of a metal selected from the group consisting of stainless steel, nickel, copper, indium, aluminium, preferably aluminium. One advantage of aluminium is that it is cheaper than other suitable alloying elements such as indium or silicon. Further advantages of aluminium are its low anode potential U, which in the case of a LiAl alloy is approximately 0.3 V vs Li/Li⁺ (comparable to graphite).

Furthermore, aluminium may provide a high specific capacity (C of an LiAl is approximately 993 Ah/kg, which corresponds to about three times that of graphite). Furthermore, the providable energy density E=C*U in the case of aluminium is very high. The aluminium may be alloyed, preferably with at least one element selected from the second main group of the periodic table, the third main group of the periodic table, the fourth main group of the periodic table, a subgroup of the periodic table and combinations thereof, wherein the at least one element is preferably selected from the group consisting of magnesium, indium, zinc, tin, silicon, manganese and combinations thereof.

In addition, the planar electrode may comprise or consist of a cathode material preferably selected from the group consisting of nickel manganese cobalt oxide, lithium iron phosphate, lithium manganese oxide, lithium nickel manganese oxide, lithium nickel oxide, lithium cobalt oxide, lithium aluminum nickel oxide, lithium manganese phosphate, lithium iron manganese phosphate, and combinations thereof.

The planar electrode may have a thickness, in a direction perpendicular to the surface of the planar electrode, in the range from 5 to 100 μm, preferably 10 to 50 μm, particularly preferably 20 to 40 μm.

Furthermore, the surface of the planar electrode may have a surface structuring. The surface structuring preferably has a structure depth in the range from 1 nm to 100 μm, wherein the surface structuring is particularly preferably selected from the group consisting of embossed surface structuring, brushed surface structuring, corrugated surface structuring, patterned surface structuring and combinations thereof.

The separator membrane may consist of at least one layer, optionally also at least one further layer (i.e., at least two layers).

The at least one layer, optionally also the at least one further layer, may comprise or consist of an electrically insulating material, wherein the material preferably has a specific electrical resistance of ≥10¹⁰ Ω·mm²/m, particularly preferably ≥10¹¹ Ω·mm²/m.

Furthermore, the at least one layer, optionally also at least one further layer, may comprise or consist of an organic material, preferably may comprise or consist of a polymeric plastic. The polymeric plastic is particularly preferably selected from the group consisting of polyolefin, fluoropolymer, polyamide, polyimide and combinations thereof, wherein the polymeric plastic is in particular selected from the group consisting of polyethylene, polypropylene, polytetrafluoroethylene, polyamide, para-aramide, polyimide and combinations thereof.

In addition, the at least one layer, optionally also the at least one further layer, may comprise or consist of an inorganic material, preferably may comprise or consist of a ceramic material, wherein the ceramic material is selected in particular from the group consisting of oxide ceramics, carbide ceramics, nitride ceramics and phosphate ceramics. The oxide ceramic may be aluminium oxide (Al₂O₃). Al₂O₃ has the advantage of being cost-effective compared to solid electrolyte salts such as lithium phosphorus sulfide. Furthermore, Al₂O₃ forms an inert protective layer and thus no unwanted side reactions. In addition, Al₂O₃ (in the form of particles) provides a porous structure, which improves electrolyte distribution and has an SEI precursor effect.

In addition, the at least one layer, optionally also the at least one further layer, may comprise or consist of an ion-conductive material.

The at least one layer, optionally also the at least one further layer, may have a thickness, in a direction perpendicular to the surface of the planar electrode, in the range from 1 μm to 300 μm, preferably in the range from 1 μm to 100 μm.

Furthermore, the at least one layer, optionally also the at least one further layer, may have a porosity in the range from 30% to 70%, preferably in the range from 40% to 60%, particularly preferably in the range from 45% to 50%.

The material arranged in at least a portion of the pores of the separator membrane, arranged in the intermediate space between the surface of the planar electrode and the first surface of the separator membrane and arranged in the pores of the surface of the planar electrode may comprise or consist of a polymer.

The polymer may comprise or consist of a non-ion-conducting polymer and/or an ion-conducting polymer. For example, the polymer may comprise or consist of a fluoropolymer and/or a polyethylene oxide, wherein the fluoropolymer is preferably selected from the group consisting of PVDF-HFP, PVDF and combinations thereof. The advantage of PVDF-HFP is that it dissolves very well in acetone and forms a network polymer, i.e., a supporting matrix that improves electrolyte distribution and serves as a fixative for an SEI.

The material arranged in at least a portion of the pores of the separator membrane, arranged in the intermediate space between the surface of the planar electrode and the first surface of the separator membrane and arranged in the pores of the surface of the planar electrode may comprise or consist of inorganic particles.

The inorganic particles may be non-electrically conductive inorganic particles, preferably non-electrically conductive ceramic particles.

The inorganic particles may further be ion-conducting inorganic particles, particularly preferably ion-conducting inorganic particles comprising or consisting of a sulfidic salt, wherein the sulfidic salt is particularly selected from the group consisting of lithium phosphorus sulfide (Li₃PS₄), lithium germanium phosphorus sulfide (Li₁₀GeP₂S₁₂), lithium silicon phosphorus sulfide, (Li₁₁Si₂PS₁₂), Li₆PS₅Cl, Li₆PS₅Br and combinations thereof. The advantage of sulfide salts is that a high ionic conductivity is achieved that is comparable to that of commercial liquid electrolytes.

The electrode may comprise a liquid electrolyte at least in a portion of the pores of the separator membrane, in the intermediate space between the surface of the planar electrode and the first surface of the separator membrane and in the pores of the surface of the planar electrode, wherein the liquid electrolyte contacts in particular the surface of the planar electrode and the first surface of the separator membrane.

The liquid electrolyte may comprise a liquid selected from the group consisting of EC, PC, DMC, EMC, DEC, VEC, VC, FEC, TBAC (acetyltributyl citrate), GTB (glycerol tributyrate), GTA (glycerol triacetate), γ-buthyrolactone and combinations thereof, wherein the liquid is preferably selected from the group consisting of PC, FEC, EC, VEC, TBAC, GTB, GTA and combinations thereof. The advantage of PC, FEC, EC, VEC, TBAC, GTB, GTA lies in their high boiling point and temperature resistance, which reduces the risk of fire and increases operational safety.

Furthermore, the liquid electrolyte may comprise a lithium conducting salt, wherein the lithium conducting salt is preferably selected from the group consisting of LiPF₆, LiClO₄, LiNO₃, C₆H₁₈LiNSi₂, F₂LiNO₄S₂, C₂F₆LiNO₄S₂, LiB[C₂O₄]₂, LiBF₄ and combinations thereof.

Apart from that, the liquid electrolyte may comprise a sodium conducting salt, wherein the sodium conducting salt is preferably selected from the group consisting of NaPF₆, NaBF₄, NaTF, NaTFSI, NaClO₄ and combinations thereof.

The electrode according to the invention may be produced by way of the method according to the invention.

According to the invention, a galvanic cell is also provided, comprising an electrode according to the invention, a counter electrode and an electrolyte.

The use of the galvanic cell according to the invention for the energy supply i) of a mobile device, preferably a mobile phone, a vehicle, an aircraft and/or a ship; and/or ii) of a stationary device, preferably a building, is proposed.

The subject matter according to the invention will be explained in greater detail on the basis of the following figure and the following example, without wishing to limit these to the specific embodiments shown here.

The figure schematically shows an electrode according to the invention, its production and its treatment with a liquid electrolyte. A planar electrode 4 is provided and a separator membrane 2 is arranged on its surface. A liquid 1, which comprises a polymer (e.g., PVDF-HFP) dissolved in an organic solvent (e.g., acetone) or consists of such a polymer, is now applied to the separator membrane 2, causing the liquid to penetrate into the pores of the separator membrane 2, into the intermediate space between the separator membrane 2 and the planar electrode 4 and into pores of the surface of the planar electrode 4. The liquid is evaporated, causing the material to remain in the pores of the separator membrane 2, in the intermediate space between the separator membrane and the planar electrode 4, and in the pores of the surface of the planar electrode 4, resulting in an enriched material layer 3. Subsequently, in a further step 5, a liquid electrolyte 6 is applied to the separator membrane 2, resulting in a composite 9 consisting of a separator membrane 7 impregnated with liquid electrolyte and a material layer 8 impregnated with liquid electrolyte 6. The material in the pores of the separator membrane 7, in the material layer 8 and in the pores of the surface of the planar electrode 4 may have been swollen by the liquid electrolyte.

### Example—Production of an Electrode for a Galvanic Cell

A polyolefin membrane is applied to a collector foil. A liquid is produced that comprises an organic solvent and a polymer dissolved in it. This liquid is pipetted onto the polyolefin membrane, causing the liquid to penetrate to the interface between the collector and the polyolefin membrane (intermediate space). The organic solvent is then evaporated, causing the polymer, which is now in the pores of the polyolefin membrane, in the intermediate space between the polyolefin membrane and the collector foil and in the pores on the surface of the collector foil, to harden.

A liquid electrolyte may now be applied to the polyolefin membrane, causing the liquid electrolyte to penetrate into the areas where the polymer is also located. The polymer may be swollen (or gelled) by the liquid electrolyte. This step may also be carried out only when the electrode is used in a galvanic cell.

### LIST OF REFERENCE SIGNS

1: liquid with material, consisting, for example, of an organic solvent (e.g., acetone) with a dissolved polymer (e.g., PVDF-HFP);
2: separator membrane (without liquid electrolyte);
3: enriched material layer that results from the material enrichment (e.g., polymer) in the pores of the separator membrane, the intermediate space and the pores of the planar electrode after the organic solvent (e.g., acetone) has evaporated;
4: planar electrode (e.g., aluminium foil);
5: step of applying liquid electrolyte;
6: liquid electrolyte;
7: separator membrane impregnated with liquid electrolyte;
8: enriched material layer impregnated with liquid electrolyte; and
9: composite of separator membrane impregnated with liquid electrolyte and material layer impregnated with liquid electrolyte.

1-18. (canceled)

19. A method for producing an electrode for a galvanic cell, comprising:
a) providing a planar electrode, wherein the planar electrode has a surface;
b) applying a first surface of a separator membrane to the surface of the planar electrode so that an intermediate space is formed between the surface of the planar electrode and the first surface of the separator membrane;
c) applying a liquid to a second surface of the separator membrane opposite the first surface, wherein the liquid comprises a solvent and a material selected from the group consisting of polymer, inorganic particles, organic particles and combinations thereof, wherein the liquid comprising its solvent and its material penetrates, by way of capillary forces, at least into the pores of the separator membrane, into the intermediate space between the surface of the planar electrode and the first surface of the separator membrane, and into pores of the surface of the planar electrode; and
d) evaporating the solvent of the liquid, whereby an electrode is created, which comprises the material of the liquid in the intermediate space between the surface of the electrode and the first surface of the separator membrane and in at least a portion of the pores, wherein the material contacts the surface of the electrode and the first surface of the separator membrane extensively.

20. The method according to claim 19, wherein the planar electrode
i) comprises an alkali metal, optionally coated on a metal selected from the group consisting of stainless steel, nickel, copper, indium, aluminium and combinations thereof; and/or
ii) comprises carbon; and/or
iii) comprises silicon, a silicon alloy and/or a silicon composite;
iv) comprises a metal selected from the group consisting of stainless steel, nickel, copper, indium, and aluminium,
v) comprises a cathode material,
vi) has a thickness in a direction perpendicular to the surface of the planar electrode in the range from 5 to 100 μm, and/or
vii) has a surface structuring on its surface.

21. The method according to claim 20, wherein the alkali metal is selected from the group consisting of lithium, sodium, and combinations thereof.

22. The method according to claim 20, wherein carbon is selected from the group consisting of graphite, graphene and combinations thereof.

23. The method according to claim 20, wherein the aluminium is alloyed with at least one element selected from the group consisting of the second main group of the periodic table, the third main group of the periodic table, the fourth main group of the periodic table, and a subgroup of the periodic table.

24. The method according to claim 23, wherein the at least one element is selected from the group consisting of magnesium, indium, zinc, tin, silicon, and manganese.

25. The method according to claim 20, wherein the planar electrode comprises a cathode material selected from the group consisting of nickel manganese cobalt oxide, lithium iron phosphate, lithium manganese oxide, lithium nickel manganese oxide, lithium nickel oxide, lithium cobalt oxide, lithium aluminum nickel oxide, lithium manganese phosphate, lithium iron manganese phosphate, and combinations thereof;

26. The method according to claim 20, wherein the surface structuring has a structure depth in the range from 1 nm to 100 μm.

27. The method according to claim 26, wherein the surface structuring is selected from the group consisting of embossed surface structuring, brushed surface structuring, patterned surface structuring, corrugated surface structuring, and combinations thereof.

28. The method according to claim 20, wherein the separator membrane consists of at least one layer which
i) comprises an electrically insulating material;
ii) comprises a polymeric plastic selected from the group consisting of polyolefin, fluoropolymer, polyamide, polyimide, and combinations thereof;
iii) comprises an inorganic material selected from the group consisting of oxide ceramics, carbide ceramics, nitride ceramics, and phosphate ceramics;
iv) comprises an ion-conductive material;
v) has a thickness, in a direction perpendicular to the surface of the planar electrode, in the range from 1 μm to 300 μm; and/or
vi) has a porosity in the range of from 30% to 70%.

29. The method according to claim 19, wherein the liquid comprises a solvent which has a boiling point at atmospheric pressure of ≤156° C., and/or has a vapor pressure at 20° C. of ≥3 hPa, wherein the solvent is optionally selected from the group consisting of acetone, DEC, DMAC, 3-hexanone, THF, butanone, 3-pentanone, toluene, p-xylene, ethanol, and mixtures thereof.

30. The method according to claim 19, wherein the material of the liquid comprises a polymer dissolved in the solvent.

31. The method according to claim 30, wherein the polymer
i) comprises a non-ion-conducting polymer and/or an ion-conducting polymer; and/or
ii) comprises a fluoropolymer and/or a polyethylene oxide; and/or
iii) is present in the liquid in a concentration from 60 wt. % to 80 wt. % in relation to the total weight of the liquid.

32. The method according to claim 19, wherein the material of the liquid comprises inorganic particles dispersed in the solvent.

33. The method according to claim 32, wherein the inorganic particles
i) are non-electrically conductive inorganic particles, and/or
ii) are ion-conducting inorganic particles.

34. The method according to claim 33, wherein the ion-conducting inorganic particles comprise a sulfidic salt.

35. The method according to claim 34, wherein the sulfidic salt is selected from the group consisting of lithium phosphorus sulfide, lithium germanium phosphorus sulfide, lithium silicon phosphorus sulfide, Li₆PS₅Cl, Li₆PS₅Br, and combinations thereof.

36. The method according to claim 19, wherein the evaporation of the solvent of the liquid takes place at a temperature in the range from 20 to 30° C.

37. The method according to claim 19, wherein the method after step d) further comprises applying a liquid electrolyte for a galvanic cell to the second surface of the separator membrane, wherein the liquid electrolyte penetrates, by way of capillary forces, at least in a portion of the pores of the separator membrane, into the intermediate space between the surface of the planar electrode and the first surface of the separator membrane and into the pores of the surface of the planar electrode, wherein the liquid electrolyte contacts the surface of the planar electrode and the first surface of the separator membrane.

38. The method according to claim 37, wherein the liquid electrolyte
i) comprises a liquid selected from the group consisting of EC, PC, DMC, EMC, DEC, VEC, VC, FEC, TBAC (acetyltributyl citrate), GTB (glycerol tributyrate), GTA (glycerol triacetate), x-buthyrolactone, and combinations thereof, and/or
ii) comprises a lithium conducting salt or a sodium conducting salt.

39. The method according to claim 38, wherein the sodium conducting salt is selected from the group consisting of NaPF₆, NaBF₄, NaTF, NaTFSI, NaClO₄ and combinations thereof; and/or wherein the lithium conducting salt is selected from the group consisting of LiPF₆, LiClO₄, LiNO₃, C₆H₁₈LiNSi₂, F₂LiNO₄S₂, C₂F₆LiNO₄S₂, LiB[C₂O₄]₂, LiBF₄ and combinations thereof.

40. An electrode for a galvanic cell comprising:
a) a planar electrode, wherein the planar electrode has a surface;
b) a separator membrane having a first surface, a second surface opposite the first surface, and pores, wherein the first surface of the separator membrane is applied to the surface of the planar electrode, and there is an intermediate space between the surface of the planar electrode and the first surface of the separator membrane;
c) a material selected from the group consisting of polymer, inorganic particles, organic particles, and combinations thereof, wherein the material is arranged in at least a portion of the pores of the separator membrane, is arranged in the intermediate space between the surface of the planar electrode and the first surface of the separator membrane, and is arranged in pores of the surface of the planar electrode, and wherein the material contacts the first surface of the separator membrane and the surface of the planar electrode extensively.

41. The electrode according to claim 40, wherein the planar electrode
i) comprises an alkali metal, optionally coated on a metal selected from the group consisting of stainless steel, nickel, copper, indium, aluminium and combinations thereof; and/or
ii) comprises carbon; and/or
iii) comprises silicon, a silicon alloy and/or a silicon composite; and/or
iv) comprises a metal selected from the group consisting of stainless steel, nickel, copper, indium, and aluminium; and/or
v) comprises a cathode material; and/or
vi) has a thickness, in a direction perpendicular to the surface of the planar electrode, in the range from 5 to 100 μm; and/or
vii) has a surface structuring on the surface of the planar electrode.

42. The electrode according to claim 41, wherein the aluminum is alloyed with at least one element selected from the second main group of the periodic table, the third main group of the periodic table, the fourth main group of the periodic table, and a subgroup of the periodic table.

43. The electrode according to claim 41, which comprises a cathode material selected from the group consisting of nickel manganese cobalt oxide, lithium iron phosphate, lithium manganese oxide, lithium nickel manganese oxide, lithium nickel oxide, lithium cobalt oxide, lithium aluminum nickel oxide, lithium manganese phosphate, lithium iron manganese phosphate, and combinations thereof.

44. The electrode according to claim 41, wherein the surface structuring has a structure depth in the range from 1 nm to 100 μm, and/or wherein the surface structuring is selected from the group consisting of embossed surface structuring, brushed surface structuring, corrugated surface structuring, patterned surface structuring, and combinations thereof.

45. The electrode according to claim 40, wherein the separator membrane consists of at least one layer, optionally also at least one further layer, wherein the at least one layer, optionally also the at least one further layer,
i) comprises an electrically insulating material, and/or
ii) comprises an organic material, and/or
iii) comprises an inorganic material, and/or
iv) comprises an ion-conductive material; and/or
v) has a thickness, in a direction perpendicular to the surface of the planar electrode, in the range from 1 μm to 300 μm; and/or
vi) has a porosity in the range of from 30% to 70%.

46. The electrode according to claim 45, which comprises a polymeric plastic selected from the group consisting of polyolefin, fluoropolymer, polyamide, polyimide, and combinations thereof.

47. The electrode according to claim 46, wherein the polymeric plastic is selected from the group consisting of polyethylene, polypropylene, polytetrafluoroethylene, polyamide, para-aramide, polyimide, and combinations thereof;

48. The electrode according to claim 40, which comprises a ceramic material selected from the group consisting of oxide ceramics, carbide ceramics, nitride ceramics, and phosphate ceramics.

49. The electrode according to claim 40, wherein the material, which is arranged in at least a portion of the pores of the separator membrane, is arranged in the intermediate space between the surface of the planar electrode and the first surface of the separator membrane and is arranged in the pores of the surface of the planar electrode, comprises a polymer.

50. The electrode according to claim 40, wherein the material, which is arranged in at least a portion of the pores of the separator membrane, is arranged in the intermediate space between the surface of the planar electrode and the first surface of the separator membrane and is arranged in the pores of the surface of the planar electrode, comprises inorganic particles, wherein the inorganic particles
i) are non-electrically conductive inorganic particles, and/or
ii) are ion-conducting inorganic particles.

51. The electrode according to claim 40, wherein a liquid electrolyte is arranged at least in a portion of the pores of the separator membrane, in the intermediate space between the surface of the planar electrode and the first surface of the separator membrane and in the pores of the surface of the planar electrode, wherein the liquid electrolyte contacts the surface of the planar electrode and the first surface of the separator membrane.

52. The electrode according to claim 49, wherein the liquid electrolyte
i) comprises a liquid selected from the group consisting of EC, PC, DMC, EMC, DEC, VEC, VC, FEC, TBAC (acetyltributyl citrate), GTB (glycerol tributyrate), GTA (glycerol triacetate), x-butyrolactone and combinations thereof, and/or
2) comprises a lithium conducting salt selected from the group consisting of LiPF₆, LiClO₄, LiNO₃, C₆H₁₈LiNSi₂, F₂LiNO₄S₂, C₂F₆LiNO₄S₂, LiB[C₂O₄]₂, LiBF₄ and combinations thereof; and/or
3) comprises a sodium conducting salt selected from the group consisting of NaPF₆, NaBF₄, NaTF, NaTFSI, NaClO₄ and combinations thereof.

53. A galvanic cell comprising an electrode according to claim 40, a counter electrode, and an electrolyte.

54. A method of providing power supply to a mobile device, a vehicle, an aircraft, a ship, or a stationary device comprising providing a galvanic cell according to claim 51 to said mobile device, vehicle, aircraft, ship, or stationary device.
